(19) United States
(12) Patent Application Publication
(10) Pub. No.: US 2025/0391444 A1
(43) Pub. Date: Dec. 25, 2025

(54) SEMICONDUCTOR DEVICE AND METHOD OF MANUFACTURING SEMICONDUCTOR DEVICE

(71) Applicant: Kioxia Corporation, Tokyo (JP)

(72) Inventors: Shogo ISHIHARA, Yatomi Aichi (JP); Hiroko ASAKURA, Yokkaichi Mie (JP); Toshiyuki MORITA, Yokkaichi Mie (JP)

(73) Assignee: Kioxia Corporation, Tokyo (JP)

(21) Appl. No.: 19/071,441

(22) Filed: Mar. 5, 2025

(30) Foreign Application Priority Data
Jun. 19, 2024 (JP) 2024-098594

(51) Int. Cl. G11C 5/06; H10B 43/10; H10B 43/27; H10D 64/66

(52) U.S. Cl. CPC G11C 5/063; H10B 43/10; H10B 43/27; H10D 64/666

(57) ABSTRACT

A semiconductor device according to an embodiment includes a semiconductor substrate, an insulating layer that is provided above the semiconductor substrate, an interconnection layer that includes a first metal-containing layer containing a first metal as a main component and a second metal-containing layer containing the first metal as the main component, the second metal-containing layer being provided on the insulating layer, the first metal-containing layer being provided on the second metal-containing layer, in which the second metal-containing layer includes the first metal and a second metal different from the first metal, and has a proportion of the first metal smaller than a proportion of the first metal in the first metal-containing layer.

### CROSS-REFERENCE TO RELATED APPLICATIONS

This application is based upon and claims the benefit of priority from Japanese Patent Application No. 2024-098594, filed on Jun. 19, 2024; the entire contents of which are incorporated herein by reference.

### FIELD

Embodiments described herein relate generally to a semiconductor device and a method of manufacturing a semiconductor device.

### BACKGROUND

In some cases, metal wiring such as a molybdenum layer is used for a semiconductor device. When the metal wiring is formed, for example, a liner layer such as a metal nitride layer is sometimes formed as a precursor, before forming a layer as a core of the metal wiring. However, when the liner layer has a low melting point, the liner layer may aggregate upon forming the core layer, and the metal wiring may have poor flatness.

### BRIEF DESCRIPTION OF THE DRAWINGS

FIGS. 1A and 1B are diagrams each illustrating an exemplary schematic configuration of a semiconductor device according to an embodiment;

FIGS. 2A to 2D are each a cross-sectional view taken in a Y direction illustrating an exemplary configuration of the semiconductor device according to an embodiment;

FIGS. 3A to 3D are diagrams each illustrating part of an exemplary procedure of a method of manufacturing a semiconductor device according to an embodiment;

FIGS. 4A to 4D are diagrams each illustrating part of an exemplary procedure of the method of manufacturing a semiconductor device according to an embodiment;

FIGS. 5A to 5C are diagrams each illustrating part of an exemplary procedure of the method of manufacturing a semiconductor device according to an embodiment;

FIGS. 6A to 6D are diagrams each illustrating part of an exemplary procedure of the method of manufacturing a semiconductor device according to an embodiment;

FIGS. 7A to 7C are diagrams each illustrating part of an exemplary procedure of the method of manufacturing a semiconductor device according to an embodiment;

FIGS. 8Aa to 8Bd are enlarged cross-sectional views sequentially illustrating part of a procedure of a replacement process for a word line according to the embodiment;

FIGS. 9Aa to 9Bc are enlarged cross-sectional views sequentially illustrating part of a procedure of the replacement process for a word line according to an embodiment;

FIGS. 10A to 10E are cross-sectional views sequentially illustrating part of a procedure of a method of forming an interconnection layer according to another embodiment; and

FIGS. 11A to 11F are cross-sectional views sequentially illustrating part of a procedure of the method of forming an interconnection layer according to the another embodiment.

### DETAILED DESCRIPTION

A semiconductor device according to an embodiment includes a semiconductor substrate, an insulating layer that is provided above the semiconductor substrate, an interconnection layer that includes a first metal-containing layer containing a first metal as a main component and a second metal-containing layer containing the first metal as a main component, the second metal-containing layer being provided on the insulating layer, the first metal-containing layer being provided on the second metal-containing layer, in which the second metal-containing layer includes the first metal and a second metal different from the first metal, and has a proportion of the first metal smaller than a proportion of the first metal in the first metal-containing layer.

Embodiments of the present invention will be described in detail below with reference to the drawings. Note that the present invention is not limited to the following embodiments. Furthermore, component elements in the following embodiments include component elements that are readily conceivable by a person skilled in the art or that are substantially equivalent.

### Embodiments

Hereinafter, a configuration of an embodiment will be described in detail with reference to the drawings. In the following embodiments, a semiconductor storage device such as a three-dimensional nonvolatile memory will be described as an example of the semiconductor device using metal wiring such as a molybdenum layer.

### (Exemplary Configuration of Semiconductor Device)

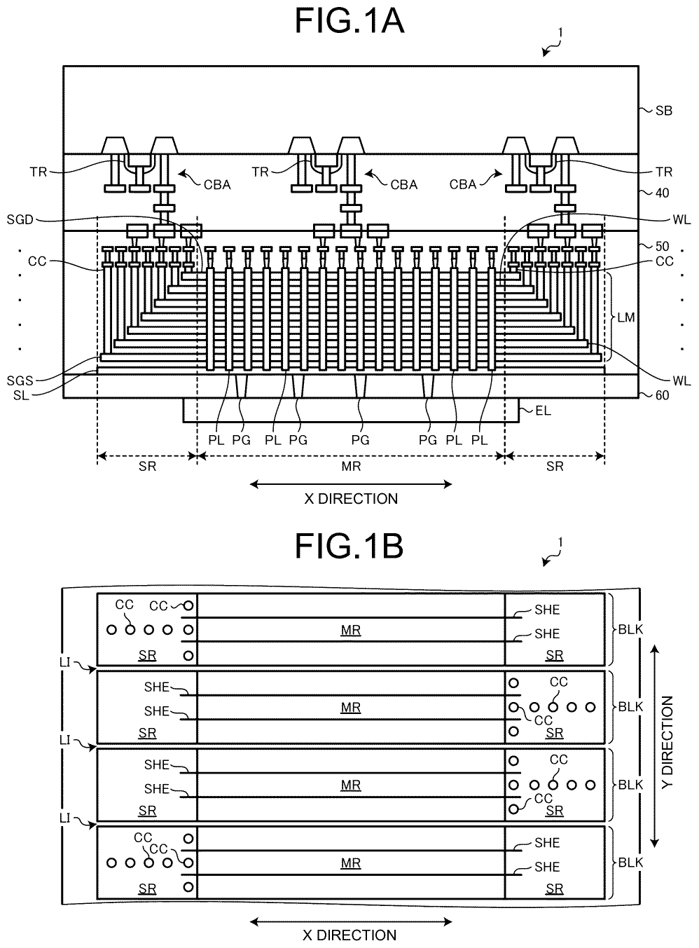

FIGS. 1A and 1B are diagrams each illustrating an exemplary schematic configuration of a semiconductor device 1 according to an embodiment. More specifically, FIG. 1A is a cross-sectional view of the semiconductor device 1 taken in the X direction, and FIG. 1B is a schematic plan view illustrating a layout of the semiconductor device 1.

However, FIG. 1A is not hatched, for ease of viewing the drawing. In addition, in FIG. 1A, configurations that are not necessarily positioned in the same cross section are illustrated, and some upper layer wirings and the like are not illustrated.

In the present specification, both the X direction and the Y direction are directions along the surfaces of a word line WL, and the X direction and the Y direction are orthogonal to each other. Furthermore, an electrical drawing direction of the word line WL is referred to as a first direction, in some cases, and the first direction is a direction oriented in the X direction. In addition, a direction intersecting the first direction is referred to as a second direction, in some cases, and the second direction is a direction oriented in the Y direction. However, the semiconductor device 1 may include a manufacturing error, and therefore, the first direction and the second direction are not necessarily orthogonal to each other.

As illustrated in FIG. 1A, the semiconductor device 1 includes a semiconductor substrate SB provided with an electrode film EL, a source line SL, one or more select gate lines SGS, a plurality of the word lines WL, one or more select gate lines SGD, and peripheral circuits CBA, in order from the lower side of the drawing.

The source line SL is arranged on the electrode film EL through an insulating layer 60. A plurality of plugs PG is arranged in the insulating layer 60, and the source line SL and the electrode film EL maintain electrical conduction via the plugs PG. Although not illustrated, an electrode pad for supplying power and a signal to the semiconductor device 1 from the outside is provided in the same layer as the electrode film EL. On the source line SL, the select gate lines SGS, the plurality of the word lines WL, and the select gate lines SGD are stacked in this order.

As illustrated in FIGS. 1A and 1B, a memory region MR is arranged at the center of the plurality of the word lines WL and the like in the X direction, and step regions SR are arranged at both ends of the plurality of the word lines WL and the like in the X direction. The memory region MR and the step regions SR are divided into a plurality of regions by a plurality of plate-shaped portions LI each penetrating the plurality of the word lines WL and the like and extending in the direction oriented in the X direction.

Note that a region arranged between the plate-shaped portions LI adjacent in the Y direction and including the memory region MR and the step regions SR is referred to a block area BLK. As will be described later, the memory region MR includes a plurality of memory cells that hold data in a nonvolatile manner, and the above block area BLK is an erase unit of these data.

Between the plate-shaped portions LI adjacent to each other in the Y direction, a plurality of separation layers SHE extending in the direction oriented in the X direction to penetrate the select gate lines SGD are arranged. The plurality of separation layers SHE extends in the direction oriented in the X direction over the entire memory region MR and partially reaches the step regions SR at both ends in the X direction.

In the memory region MR, a plurality of pillars PL penetrating the word lines WL and the select gate lines SGD and SGS in a stacking direction thereof is arranged. The pillars PL each have a lower end reaching the source line SL. A plurality of memory cells is formed at intersections between the pillars PL and the word lines WL. Therefore, the semiconductor device 1 is configured as, for example, the three-dimensional nonvolatile memory in which the memory cells are three-dimensionally arranged in the memory region MR. Therefore, the semiconductor device 1 of the embodiment is also a semiconductor storage device.

In each of the step regions SR, the pluralities of the word lines WL and the select gate lines SGD and SGS are processed into a stepped shape and terminate. At this time, as away from the memory region MR in the X direction, each of the pluralities of the word lines WL and the select gate lines SGD and SGS, each constituting a terrace portion, is positioned on a lower layer side relative to an upper layer side, having a height position of the terrace portion lowered toward the source line SL.

In the present specification, a direction in which terrace surfaces of the pluralities of the word lines WL and the select gate lines SGD and SGS face is defined as an upper side of the semiconductor device 1.

Each of the separation layers SHE described above extends from the memory region MR to a portion of each step region SR where the select gate lines SGD are processed into the stepped shape. Therefore, the select gate lines SGD are divided into a plurality of regions, in one block area BLK. In other words, the separation layers SHE penetrate portions of layers above the plurality of the word lines WL to section these upper layer portions into a plurality of patterns of the select gate lines SGD.

Contacts CC connected to the word lines WL and the select gate lines SGD and SGS of the respective layers are arranged at the terrace portions in the respective steps constituted by the pluralities of the word lines WL and the select gate lines SGD and SGS. In the word lines WL and the select gate lines SGS, one contact CC is connected for each layer. In the select gate lines SGD, one contact CC is connected for each section separated by the separation layers SHE per layer.

Here, in one block area BLK, a plurality of the contacts CC is arranged on one of the step regions SR on both sides in the X direction. When viewed on one side in the X direction, for example, a plurality of the contacts CC is arranged every two block areas BLK.

In other words, in the example of FIG. 1B, a plurality of the contacts CC is arranged, for example, in a step region SR on the left side of the drawing, of the step regions SR at both ends in the X direction, in the uppermost block area BLK in the drawing. In addition, in block areas BLK one step and two steps below the block area BLK described above, a plurality of the contacts CC is arranged in step regions SR on the right side of the drawing, of the step regions SR at both ends in the X direction. Furthermore, in the lowermost block area BLK in the drawing, a plurality of the contacts CC is arranged again in a step region SR on the left side of the drawing.

Therefore, in FIG. 1A, the contacts CC in the step regions SR at both ends in the X direction belong to different block areas BLK, and are not actually located in the same cross section.

The word lines WL and the like stacked in multiple layers are individually drawn out by these contacts CC. More specifically, a write voltage, a read voltage, and the like are applied from these contacts CC to the memory cells included in the memory region MR at the center of the plurality of the word lines WL, via the word lines WL located at the same height positions as the memory cells.

The pluralities of the word lines WL and the select gate lines SGD and SGS, the pillars PL, and the contacts CC are covered with an insulating layer 50. The insulating layer 50 also extends around these configurations including the plurality of the word lines WL and the like.

The semiconductor substrate SB above the insulating layer 50 covering the above configurations is, for example, a silicon substrate or the like. The semiconductor substrate SB has a surface on which the peripheral circuits CBA including transistors TR, wirings, and the like are arranged. Various voltages applied from the contacts CC to the memory cells are controlled by the peripheral circuits CBA electrically connected to the contacts CC. Therefore, the peripheral circuits CBA control the electrical operation of the memory cells.

The peripheral circuits CBA are covered with an insulating layer 40, and the insulating layer 40 is joined with the insulating layer 50 covering the plurality of the word lines WL and the like to constitute the semiconductor device 1 including the configurations of the pluralities of the word lines WL and the select gate lines SGD and SGS, the pillars PL, the contacts CC, and the like, and the peripheral circuits CBA.

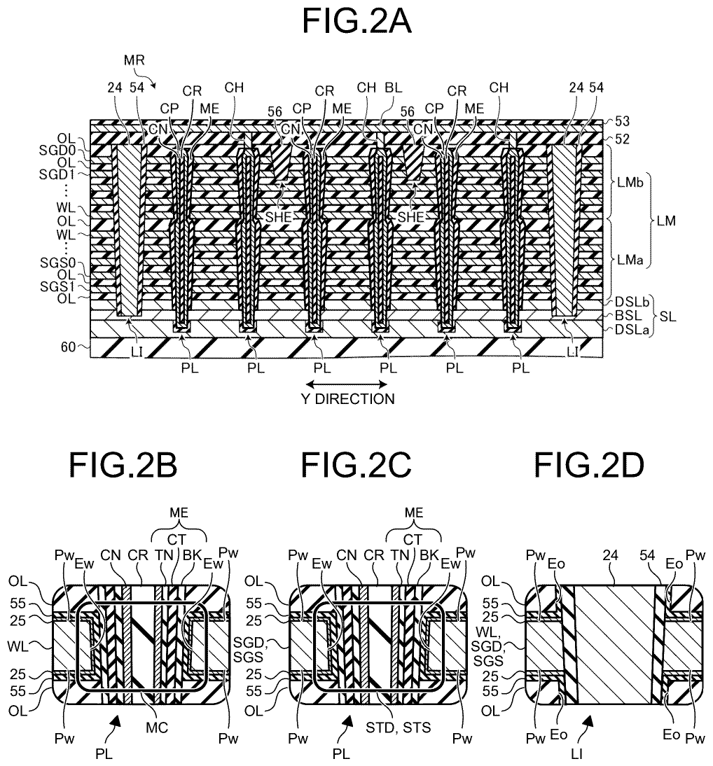

Next, a detailed exemplary configuration of the semiconductor device 1 will be described with reference to FIGS. 2A to 2D. FIGS. 2A to 2D are each a cross-sectional view taken in a Y direction illustrating an exemplary configuration of the semiconductor device 1 according to an embodiment.

More specifically, FIG. 2A is a cross-sectional view of the memory region MR of the semiconductor device 1. In FIG. 2A, structures below the insulating layer 60 and above an insulating layer 53 which is described later are not illustrated.

FIG. 2B is an enlarged cross-sectional view of a pillar PL at a height position of a word line WL. FIG. 2C is an enlarged cross-sectional view of a pillar PL at a height position of each of the select gate lines SGD and SGS. FIG. 2D is an enlarged cross-sectional view of a plate-shaped portion LI at a height position of each of the word line WL and the select gate lines SGD and SGS.

As illustrated in FIG. 2A, the source line SL has a layer structure in which, for example, a lower source line DSLa, an intermediate source line BSL, and an upper source line DSLb are stacked in this order, on the insulating layer 60. The lower source line DSLa, the intermediate source line BSL, and the upper source line DSLb are, for example, a polysilicon layer. Of the source lines described above, at least the intermediate source line BSL may be a conductive polysilicon layer or the like in which impurities are diffused.

Note that the source line SL is connected to each of the peripheral circuits CBA through the electrode film EL by a through contact, which is not illustrated, extending from the electrode film EL to each of the peripheral circuits CBA in the insulating layer 50 described above outside a stacked body LM.

The stacked body LM is arranged on the source line SL. The stacked body LM includes stacked bodies LMa and LMb in which a plurality of the word lines WL and a plurality of insulating layers OL are alternately stacked one by one.

The stacked body LMa is arranged above the source line SL. A plurality of select gate lines SGS0 and SGS1 is arranged in this order from an upper layer side of the stacked body LMa through the insulating layers OL, in lower layers below the word line WL in the lowermost layer of the stacked body LMa. The stacked body LMb is arranged on the stacked body LMa. A plurality of select gate lines SGD0 and SGD1 is arranged in this order from an upper layer side of the stacked body LMb through the insulating layers OL, in upper layers above the word line WL in the uppermost layer of the stacked body LMb.

However, any number of the word lines WL and any number of the select gate lines SGD and SGS may be stacked in the stacked body LM. The word lines WL and the select gate lines SGD and SGS are, for example, a molybdenum (Mo) layer. The insulating layers OL are, for example, a silicon oxide layer.

Here, the word lines WL and the select gate lines SGD and SGS are more specifically a metal layer including a simple substance of molybdenum. The simple substance of molybdenum means that a metal intentionally contained in constituent materials of the word line WL and the like is only molybdenum. In addition, the simple substance of molybdenum means that the word line WL and the like have a maximum proportion of molybdenum, without a component whose proportion is higher than that of molybdenum, among other components such as impurities that can be mixed in the manufacturing process.

As illustrated in FIGS. 2B to 2D, the pluralities of the word lines WL and the select gate lines SGD and SGS have both side surfaces in the stacking direction of the stacked body LM that are covered with a metal nitride layer 25 and a metal oxide layer 55 in this order. Note that in the present embodiment, a constituent material composition which is described later is analyzed using, for example, energy dispersive X-ray spectroscopy (EDS). The pluralities of the word lines WL and the select gate lines SGD and SGS and the metal nitride layer 25 are each analyzed using, for example, EDS. At that time, in the EDS, the boundaries between the pluralities of the word lines WL and the select gate lines SGD and SGS and the metal nitride layer 25 cannot be clearly determined in some cases. However, a metal content is different between layers, and therefore, even when the boundaries between the pluralities of the word lines WL, the select gate lines SGD and SGS, and the metal nitride layer 25 cannot be clearly determined in EDS, the pluralities of the word lines WL, the select gate lines SGD and SGS, and the metal nitride layer 25 each having a constituent material composition which is described later are included in the present configuration.

The metal nitride layer 25 is, for example, a composite metal nitride layer containing molybdenum as a main component and containing the molybdenum and another metal. Containing molybdenum as the main component in the metal nitride layer 25 means, for example, that the constituent material of the metal nitride layer 25 has a maximum proportion of molybdenum, and the proportion of the other metal is less than the proportion of molybdenum. At this time, the ratio of the other metal to molybdenum in the metal nitride layer 25 is preferably, for example, 0.5 atom % or more and 3 atom % or less. In addition, it also means that there is not a component whose proportion is higher than that of molybdenum, among other components such as impurities that can be mixed in the manufacturing process. Furthermore, the metal nitride layer 25 and the pluralities of the word lines WL and the select gate lines SGD and SGS are different in the constituent material composition. The proportion of molybdenum in the metal nitride layer 25 is lower than the proportion of molybdenum in each of the word lines WL and the select gate lines SGD and SGS.

For the other metal, a metal having a property of being alloyed with molybdenum can be used, and for example, at least one of titanium (Ti), aluminum (Al), nickel (Ni), niobium (Nb), or cobalt (Co) may be used.

Therefore, at least some or all of the other metals mentioned above are alloyed with molybdenum in the metal nitride layer 25, and it can also be said that the metal nitride layer 25 is a molybdenum alloy layer. In addition, the metal nitride layer 25 in which the above other metal is alloyed with molybdenum has a melting point higher than that of a metal layer, a metal nitride layer, or the like which does not contain the other metal to be alloyed with molybdenum, such as the word line WL and the like described above.

As described later, the metal nitride layer 25 is a layer serving as a precursor when the word line WL and the select gate lines SGD and SGS such as the molybdenum layer or the like are formed.

The metal oxide layer 55 is, for example, an aluminum oxide (Al₂O₃) layer or the like, and functions as a block insulating layer in a memory cell MC, which will be described later.

As illustrated in FIG. 2A, the stacked body LM has an upper surface that is covered with an insulating layer 52. The insulating layer 52 is covered with the insulating layer 53. Each of the insulating layers 52 and 53 partially constitutes the insulating layer 50 in FIG. 1A.

As described above, the stacked body LM is divided in the Y direction by the plurality of plate-shaped portions LI. In other words, the plate-shaped portions LI are arranged side by side in the Y direction and extend in the stacking direction of the stacked body LM and in the direction oriented in the X direction.

In this manner, each of the plate-shaped portions LI continuously extends in the stacked body LM from one end to the other end of the stacked body LM in the X direction. The plate-shaped portion LI penetrates the stacked body LM and the upper source line DSLb and reaches the intermediate source line BSL.

The plate-shaped portion LI has, for example, a tapered shape having a width in the Y direction decreasing from an upper end toward a lower end. Alternatively, the plate-shaped portion LI has, for example, a bowing shape having a width in the Y direction maximized at a predetermined position between the upper end and the lower end.

Each of the plate-shaped portions LI includes an insulating layer 54 and a conductive layer 24. The insulating layer 54 is, for example, a silicon oxide layer or the like. The conductive layer 24 is, for example, a tungsten layer or a conductive polysilicon layer.

The insulating layer 54 covers side walls of the plate-shaped portion LI facing each other in the Y direction. The inside of the insulating layer 54 is filled with the conductive layer 24. However, instead of the conductive layer 24, a plate-shaped member filled with an insulating layer may penetrate the stacked body LM and extend in the direction oriented in the X direction to divide the stacked body LM in the Y direction.

Note that FIG. 2D illustrates details of a layer structure of the word line WL, the select gate lines SGD and SGS and the like, the metal nitride layer 25, and the metal oxide layer 55, which have been described above, in the vicinity of the plate-shaped portion LI.

As illustrated in FIG. 2D, the metal oxide layer 55, among the metal nitride layer 25 and the metal oxide layer 55 that cover both surfaces Pw of the word line WL or the like in the stacking direction, further extends from both surfaces Pw of the word line WL or the like, toward an end surface Eo of each of the insulating layers OL facing a side surface of the plate-shaped portion LI, on the side surface of the plate-shaped portion LI. In other words, on the end surface Eo of the insulating layer OL, the metal oxide layer 55 is interposed between the insulating layer OL and the insulating layer 54 of the plate-shaped portion LI.

Between the plate-shaped portions LI adjacent in the Y direction, the plurality of separation layers SHE is arranged that penetrates an upper layer portion of the stacked body LMb and extends in the direction oriented in the X direction. These separation layers SHE are an insulating layer 56 such as a silicon oxide layer that penetrates the select gate lines SGD0 and SGD1 and reach the insulating layer OL immediately below the select gate line SGD1.

In other words, these separation layers SHE penetrating the upper layer portion of the stacked body LMb extend in the X direction between the plate-shaped portions LI through the memory region MR and part of the step regions SR, and therefore, the upper layer portion of the stacked body LMb is sectioned into the select gate lines SGD0 and SGD1 described above.

In the memory region MR, the plurality of pillars PL penetrating the stacked body LM, the upper source line DSLb, and the intermediate source line BSL and reaching the lower source line DSLa is dispersedly arranged.

The plurality of pillars PL is arranged, for example, in a staggered arrangement when viewed from the stacking direction of the stacked body LM. Each of the pillars PL has, for example, a circular shape, elliptical shape, oval shape, or the like in cross-sectional shape in a direction oriented in a layer direction of the stacked body LM, that is, in a direction along an XY plane.

In addition, each of the pillars PL has a portion penetrating the stacked body LMa and a portion penetrating the stacked body LMb, each of which has a tapered shape having a diameter and a cross-sectional area, decreasing from the upper layer side to the lower layer side. Alternatively, the pillar PL has the portion penetrating the stacked body LMa and the portion penetrating the stacked body LMb, each of which has a bowing shape having a diameter and a cross-sectional area, maximized at, for example, a predetermined position between the upper layer side and the lower layer side.

Each of the plurality of pillars PL includes a memory layer ME extending in the stacked body LM in the stacking direction, a channel layer CN penetrating the stacked body LM and connected to the intermediate source line BSL, a cap layer CP covering an upper surface of the channel layer CN, and a core layer CR serving as a core material of the pillar PL.

More specifically, the channel layer CN is in direct contact with the intermediate source line BSL at a depth position of the intermediate source line BSL. In other words, the memory layer ME is arranged on a side surface of the pillar PL except for the depth position of the intermediate source line BSL. In addition, the memory layer ME is also arranged on a bottom surface of the pillar PL reaching a depth of the lower source line DSLa.

As described above, the channel layer CN further penetrates the stacked body LM, the upper source line DSLb, and the intermediate source line BSL inside the memory layer ME, reaches the depth of the lower source line DSLa, with a side surface in contact with the intermediate source line BSL. Therefore, the channel layer CN is electrically connected to the source line SL including the intermediate source line BSL.

Furthermore, the cap layer CP is arranged at an upper end of the pillar PL so as to cover at least an upper end of the channel layer CN, and is connected to the channel layer CN. Furthermore, the cap layer CP is connected to a bit line BL arranged in the insulating layer 53 via a plug CH arranged in the insulating layer 52. The bit line BL extends above the stacked body LM in the direction oriented in the Y direction so as to intersect the drawing direction of the word line WL.

Note that in FIG. 2A, the plugs CH are connected only to three pillars PL, among six pillars PL, that penetrate three separated select gate lines SGD and are electrically connected to the bit line BL illustrated in FIG. 2A. The other pillars PL are connected to another bit lines BL extending in the direction oriented in the Y direction, in parallel with the bit line BL illustrated in FIG. 2A, via plugs CH which are not illustrated in FIG. 2A, at positions different from those illustrated in the cross section of FIG. 2A.

As illustrated in FIGS. 2B and 2C, the memory layer ME has a layer structure including a block insulating layer BK, a tunnel insulating layer TN, and a charge storage layer CT.

The block insulating layer BK and the tunnel insulating layer IN of the memory layer ME, and the core layer CR are, for example, a silicon oxide layer or the like. The charge storage layer CT is, for example, a silicon nitride layer or the like. The channel layer CN and the cap layer CP are semiconductor layers such as a polysilicon layer or an amorphous silicon layer.

As illustrated in FIG. 2B, with the above configuration, each memory cell MC is formed in a portion facing each word line WL on the side surface of each pillar PL. When a predetermined voltage is applied from the word line WL, data is written to and read from the memory cell MC.

In addition, a select gate STD is formed in portions where the side surfaces of each pillar PL face the select gate lines SGD0 and SGD1 positioned above the word lines WL. In addition, a select gate STS is formed in portions where the side surfaces of each pillar PL face the select gate lines SGS0 and SGS1 positioned below the word lines WL.

When a predetermined voltage is applied from the select gate lines SGD and SGS, the select gates STD and STS are turned on or off, enabling to bring each memory cell MC on each pillar PL to which the select gates STD and STS belong, into a selected state or a non-selected state.

Note that FIGS. 2B and 2C illustrate details of a layer structure of the word line WL or the like, the metal nitride layer 25, and the metal oxide layer 55, which have been described above, in the vicinity of the pillar PL.

In other words, each of the metal nitride layer 25 and the metal oxide layer 55 that cover both surfaces Pw of the word line WL and or like in the stacking direction further extends from both surfaces Pw of the word line WL or the like, toward an end surface Ew of the word line WL or the like facing the side surface of the pillar PL, on the side surface of the pillar PL. In other words, on the end surface Ew of the word line WL or the like, the metal nitride layer 25 and the metal oxide layer 55 are interposed between the word line WL or the like and the block insulating layer BK of the pillar PL in this order, from the side of the word line WL or the like.

Note that in the semiconductor device 1 of the embodiment, the word line WL and the select gate lines SGD and SGS are examples of a first metal-containing layer included in the interconnection layer. The metal nitride layer 25 is an example of the second metal-containing layer included in the interconnection layer. In addition, a configuration including the word lines WL, the select gate lines SGD and SGS, and the metal nitride layer 25 is an example of the interconnection layer.

### (Method of Manufacturing Semiconductor Device)

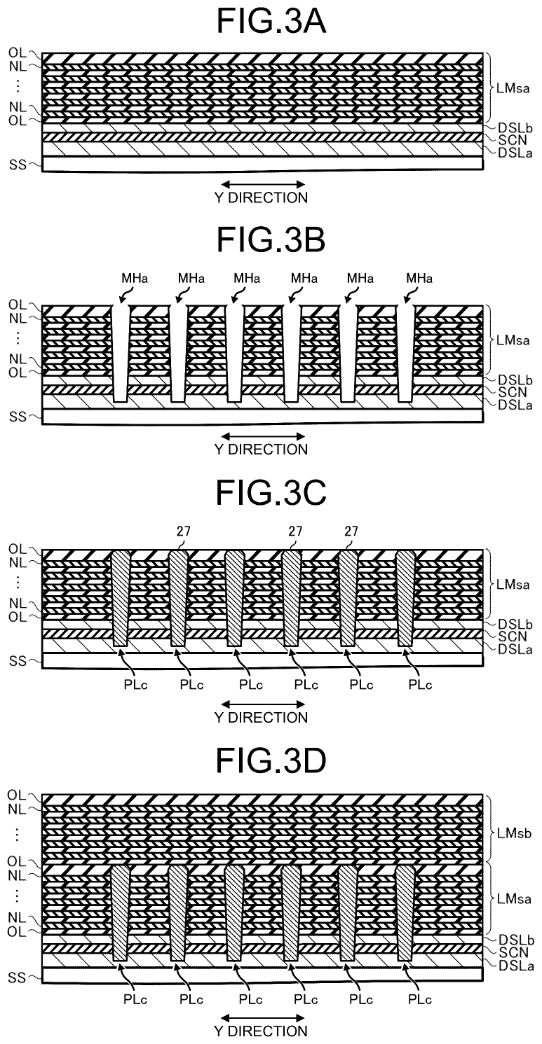

Next, a method of manufacturing the semiconductor device 1 according to an embodiment will be described with reference to FIGS. 3A to 9Bc. FIGS. 3A to 7C, among FIGS. 3A to 9Bc, are diagrams sequentially illustrating a procedure of the method of manufacturing the semiconductor device 1 according to the embodiment. FIGS. 3A to 7C each illustrate a cross section taken along the Y direction of a region serving as the memory region MR later.

As illustrated in FIG. 3A, the lower source line DSLa, an intermediate sacrificial layer SCN, and the upper source line DSLb are formed in this order on a support substrate SS.

For the support substrate SS, a semiconductor substrate such as a silicon substrate, an insulating substrate such as a ceramic substrate, a conductive substrate, or the like can be used. The insulating layer 60 (see FIG. 2A and the like) described above may be formed on an upper surface side of the support substrate SS. The intermediate sacrificial layer SCN is, for example, a silicon nitride layer or the like, and is a layer to be replaced with a polysilicon layer or the like later to serve as the intermediate source line BSL.

A stacked body LMsa in which a plurality of insulating layers NL and a plurality of the insulating layers OL are alternately stacked one by one is formed on the upper source line DSLb. Each of the insulating layers NL is, for example, a silicon nitride layer or the like, and functions as a sacrificial layer that is replaced with a conductive material later to serve as each word line WL or each select gate line SGS.

Thereafter, although not illustrated, the insulating layers NL and the insulating layers OL are processed into a stepped shape, in a partial region of the stacked body LMsa. Such processing is enabled by repeating slimming of a mask pattern such as a photoresist layer and etching of the insulating layers NL and the insulating layers OL of the stacked body LMsa a plurality of times.

In other words, the mask pattern is formed on an upper surface of the stacked body LMsa to etch away the insulating layers NL and the insulating layers OL in exposed portions one by one. In addition, in processing with oxygen plasma or the like, receding of an end of the mask pattern exposes a new upper surface of the stacked body LMsa, and the insulating layers NL and the insulating layers OL are further etched away one by one. Repeating such processing a plurality of times forms the stacked body LMsa having the stepped shape at both ends in the X direction.

As illustrated in FIG. 3B, a plurality of memory holes MHa extending in a stacking direction of the stacked body LMsa is formed. The plurality of memory holes MHa penetrates the stacked body LMsa, the upper source line DSLb, and the intermediate sacrificial layer SCN, and reaches the lower source line DSLa. These memory holes MHa are portions that serve as lower structures of the pillars PL later.

As illustrated in FIG. 3C, the memory holes MHa are filled with sacrificial layers 27 such as an amorphous silicon layer or a CVD-carbon layer. Therefore, pillars PLc are formed that are obtained by filling the plurality of memory holes MHa with the sacrificial layers 27.

As illustrated in FIG. 3D, a stacked body LMsb that covers the stacked body LMsa and in which a plurality of insulating layers NL and a plurality of insulating layers OL are alternately stacked one by one is formed. Each of the insulating layers NL of the stacked body LMsb functions as a sacrificial layer that is replaced with a conductive layer later to serve as each word line WL or each select gate line SGD.

Thereafter, although not illustrated, the insulating layers NL and the insulating layers OL are processed into a stepped shape in a partial region of the stacked body LMsb. Such processing is enabled by repeating slimming of a mask pattern such as a photoresist layer and etching of the insulating layers NL and the insulating layers OL of the stacked body LMsb a plurality of times, as in the processing for the stacked body LMsa described above.

At this time, the uppermost step of a stepped portion having been formed in the stacked body LMsa and the lowermost step of a stepped portion formed in the stacked body LMsb are brought closer to each other to form a shape of steps continued from a lower layer side of the stacked body LMsa to an upper layer side of the stacked body LMsb. Therefore, the stacked bodies LMsa and LMsb are formed in which the step regions SR having the stepped shapes are formed at both ends in the X direction, from the stacked body LMsa to the stacked body LMsb.

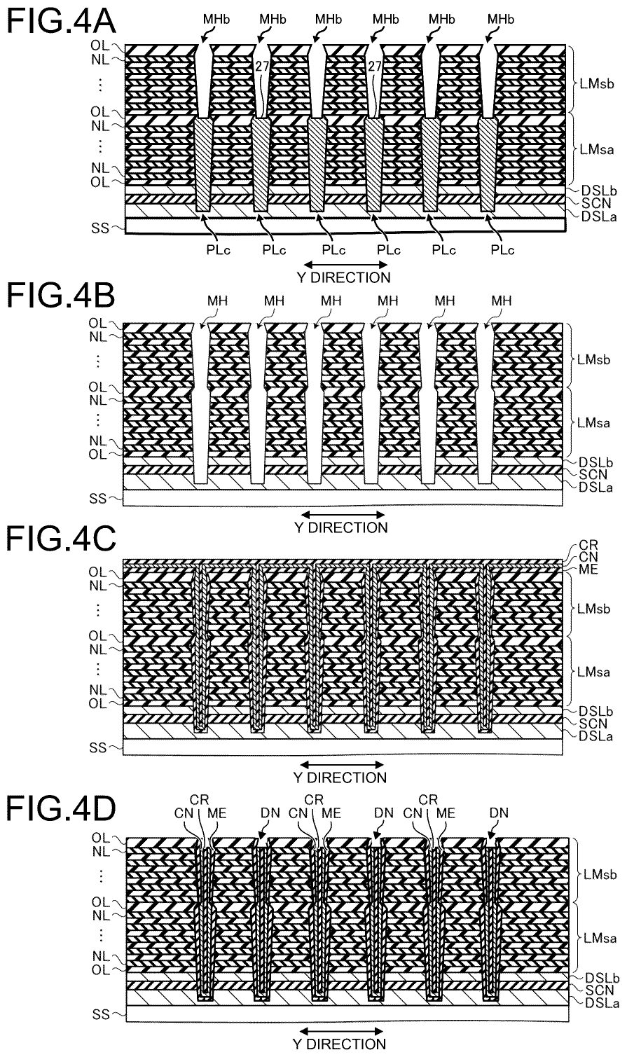

As illustrated in FIG. 4A, a plurality of memory holes MHb is formed that penetrates the stacked body LMsb and connected to a plurality of the pillars PLC having formed in the stacked body LMsa. Each of the memory holes MHb is a portion that serves as an upper structure of each pillar PL later.

As illustrated in FIG. 4B, each of the sacrificial layers 27 is removed from each of the pillars PLc at the bottom of the memory hole MHb. Therefore, the memory holes MHa are opened at the bottoms of the plurality of memory holes MHb, and a plurality of memory holes MH is formed that penetrates the stacked bodies LMsb and LMsa, the upper source line DSLb, and the intermediate sacrificial layer SCN and reaches the lower source line DSLa.

Note that, in a case where the sacrificial layers 27 filled in the pillars PLc is the CVD-carbon layer or the like, the sacrificial layers 27 can be collectively removed from these pillars PLC when the mask pattern or the like used in forming the memory holes MHb in FIG. 4A described above is removed by ashing or the like using oxygen plasma.

As illustrated in FIG. 4C, the memory layer ME, the channel layer CN, and the core layer CR are formed in this order in each of the memory holes MH. Therefore, the memory layer ME and the channel layer CN are formed on a side surface of the memory hole MH and a bottom surface thereof from which the lower source line DSLa is exposed, and the core layer CR is filled in the center portion of the memory hole MH. The memory layer ME, the channel layer CN, and the core layer CR are also formed in this order on an upper surface of the stacked body LMsb.

As illustrated in FIG. 4D, the core layer CR, the channel layer CN, and the memory layer ME on the upper surface of the stacked body LMsb are sequentially removed by chemical mechanical polishing (CMP) or the like. In addition, dents DN are formed in the upper ends of the core layer CR and the channel layer CN.

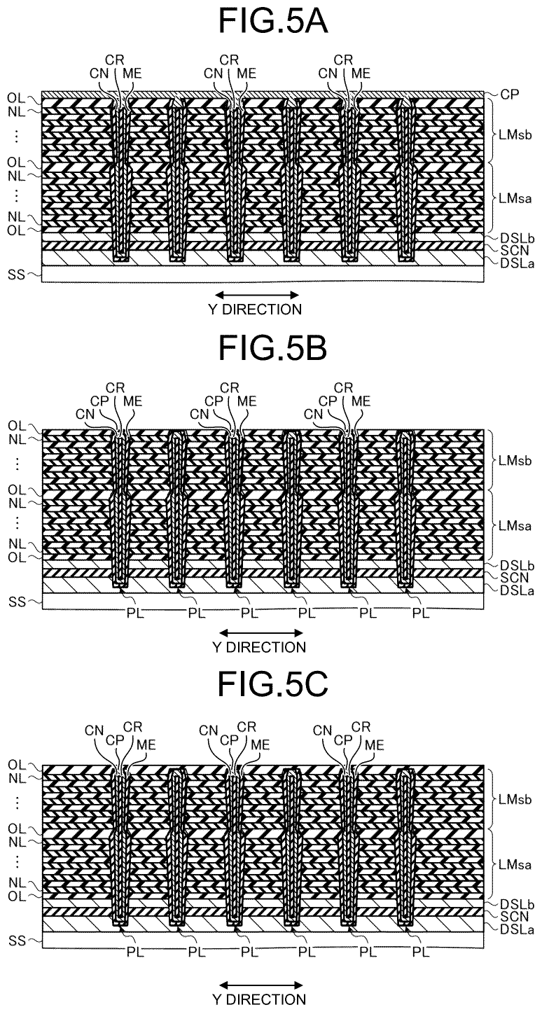

As illustrated in FIG. 5A, the cap layer CP is formed in the dents DN at the upper ends of the memory holes MH. The cap layer CP is also formed on the upper surface of the stacked body LMsb.

As illustrated in FIG. 5B, the cap layer CP on the upper surface of the stacked body LMsb is removed by CMP or the like to form the cap layer CP arranged at the upper end of each of the memory holes MH.

As illustrated in FIG. 5C, a thickness of the insulating layer OL in the uppermost layer of the stacked body LMsb decreases due to the CMP or the like, and therefore, the insulating layer OL is further stacked. Therefore, the pillars PL are formed, in each of which the cap layer CP is buried in the uppermost insulating layer OL. However, at this point, the memory layer ME covers the entire sidewall of each pillar PL, and part of the side surface of the channel layer CN is not exposed from the memory layer ME.

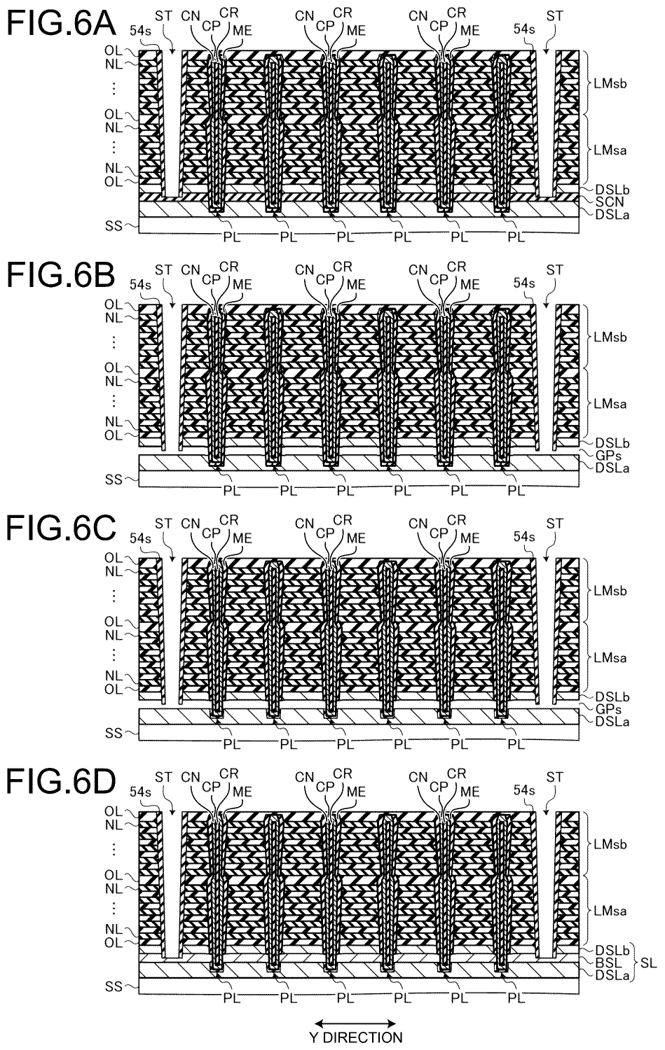

As illustrated in FIG. 6A, slits ST are formed that penetrate the stacked bodies LMsb and LMsa and the upper source line DSLb and reaches the intermediate sacrificial layer SCN. Furthermore, an insulating layer 54s is formed on side walls of each of the slits ST facing each other in the Y direction. The slit ST also extends in the X direction, in the stacked bodies LMsa and LMsb.

As illustrated in FIG. 6B, a removing liquid for the intermediate sacrificial layer SCN, such as thermal phosphoric acid, is caused to flow through the slit ST whose side walls are protected by the insulating layer 54s to remove the intermediate sacrificial layer SCN held between the lower source line DSLa and the upper source line DSLb.

Therefore, a gap layer GPs is formed between the lower source line DSLa and the upper source line DSLb. Furthermore, the memory layer ME on an outer peripheral portion of the pillar PL is partially exposed in the gap layer GPs. At this time, the side walls of the slit ST are protected by the insulating layer 54s, thus, suppressing removal of even the insulating layers NL in the stacked bodies LMsa and LMsb.

As illustrated in FIG. 6C, a chemical liquid is caused to appropriately flow into the gap layer GPs through the slit ST to sequentially remove the block insulating layer BK, the charge storage layer CT, and the tunnel insulating layer TN (see FIGS. 2B and 2C) of the memory layer ME exposed in the gap layer GPs. Therefore, the memory layer ME is partially removed from the side walls of the pillar PL, and the channel layer CN on the inside is exposed in the gap layer GPS.

As illustrated in FIG. 6D, for example, a source gas for amorphous silicon or the like is injected from the slit ST whose side walls are protected by the insulating layer 54s to fill the gap layer GPs with amorphous silicon or the like. In addition, the support substrate SS is heat-treated for polycrystallization of amorphous silicon filled in the gap layer GPs, thereby forming the intermediate source line BSL containing polysilicon or the like.

Therefore, part of a side surface of the channel layer CN of the pillar PL is connected to the source line SL via the intermediate source line BSL.

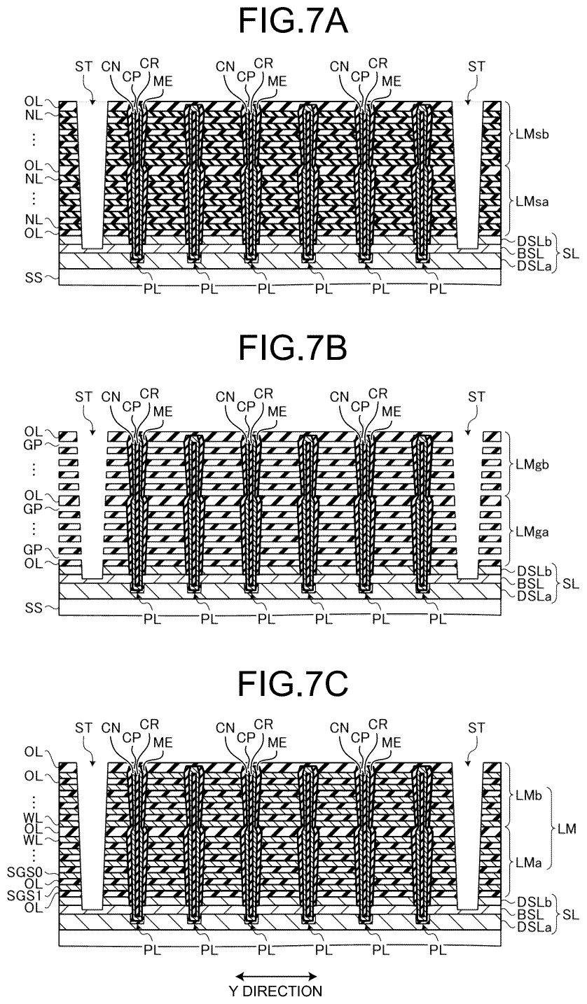

As illustrated in FIG. 7A, the insulating layer 54s on the side walls of each slit ST is temporarily removed.

As illustrated in FIG. 7B, a removing liquid for the insulating layer NL, such as thermal phosphoric acid, is caused to flow from the slit ST into the stacked bodies LMsa and LMsb to remove the insulating layers NL of the stacked bodies LMsa and LMsb. Therefore, stacked bodies LMga and LMgb are formed that have a plurality of gap layers GP obtained by removing the insulating layers NL between the insulating layers OL.

The stacked bodies LMga and LMgb including the plurality of gap layers GP have a fragile structure. The plurality of pillars PL support such fragile stacked bodies LMga and LMgb. This configuration suppresses bending of the insulating layers OL remaining in the stacked bodies LMga and LMgb and distortion or collapse of the stacked bodies LMga and LMgb.

As illustrated in FIG. 7C, a source gas for a conductive material such as molybdenum is injected from the slit ST into the stacked bodies LMga and LMgb, and the gap layers GP of the stacked bodies LMga and LMgb are filled with the conductive material to form the plurality of the word lines WL and the like. Therefore, the stacked body LM including the stacked bodies LMa and LMb in which the plurality of the word lines WL and the like and the plurality of insulating layers OL are alternately stacked one by one is formed.

As described above, the process of forming the intermediate source line BSL from the intermediate sacrificial layer SCN and the process of forming the word lines WL from the insulating layers NL are also referred to as a replacement process.

Then, the insulating layer 54 is formed on the side walls of the slit ST, and the conductive layer 24 is filled in the insulating layer 54 to form each of the plate-shaped portions LI. However, the insulating layer 54 and the like may be filled in the slit ST without forming the conductive layer 24 to form the plate-shaped member.

Thereafter, a groove penetrating one or a plurality of conductive layers including an uppermost conductive layer of the stacked body LMb is formed, the insulating layer 56 is filled therein, forming each of the separation layers SHE to section these conductive layers into the patterns of the select gate lines SGD.

In addition, the plurality of the contacts CC are formed that reaches the word lines WL and the select gate lines SGD and SGS constituting the respective steps of the stepped structure of each step region SR, from above the step region SR.

In addition, the insulating layer 52 is formed on the upper surface of the stacked body LM, and the plugs CH connected to the pillars PL and plugs connected to the contacts CC are formed through the insulating layer 52. Furthermore, the insulating layer 53 is formed on the insulating layer 52, and the bit line BL connected to the plugs CH, the upper layer wirings connected to the contacts CC via the plugs, and the like are formed. In addition, an electrode pad or the like for electrical conduction with each of the peripheral circuits CBA is formed on an upper surface of the insulating layer 53.

For example, the plugs CH, the bit lines BL, and the like may be collectively formed by using a dual damascene method or the like.

In addition, the peripheral circuits CBA are formed on the semiconductor substrate SB separated from the support substrate SS on which the stacked body LM is formed, and are covered with the insulating layer 40. In the insulating layer 40, contacts, vias, wirings, and the like that withdraw the peripheral circuits CBA to a surface of the insulating layer 40 are formed and each connected to an electrode pad or the like formed on the upper surface of the insulating layer 40.

Subsequently, the support substrate SS and the semiconductor substrate SB are bonded to each other by using the insulating layers 50 and 40, and the electrode pads in the insulating layers 50 and 40 are connected. Thereafter, the support substrate SS is removed to expose the source line SL, and the electrode film EL is connected through the insulating layer 60 in which the plugs PG are formed.

As described above, the semiconductor device 1 according to the embodiment is manufactured.

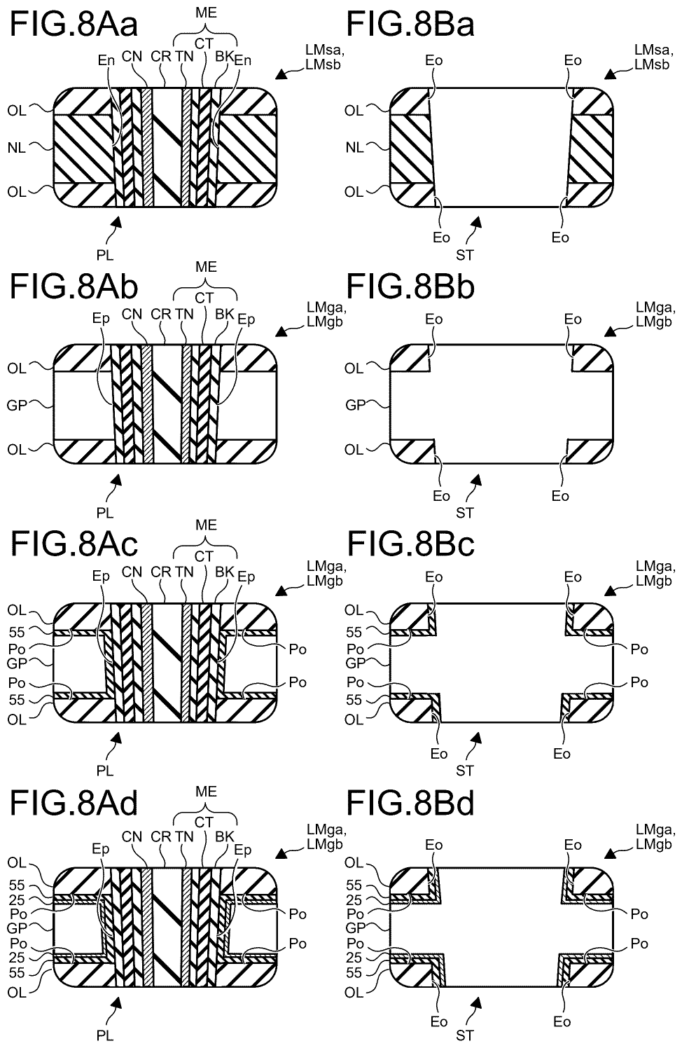

Next, details of the replacement process for the word lines WL will be described with reference to FIGS. 8Aa to 9Bc. FIGS. 8Aa to 9Bc are enlarged cross-sectional views sequentially illustrating part of a procedure of a replacement process for a word line WL according to an embodiment.

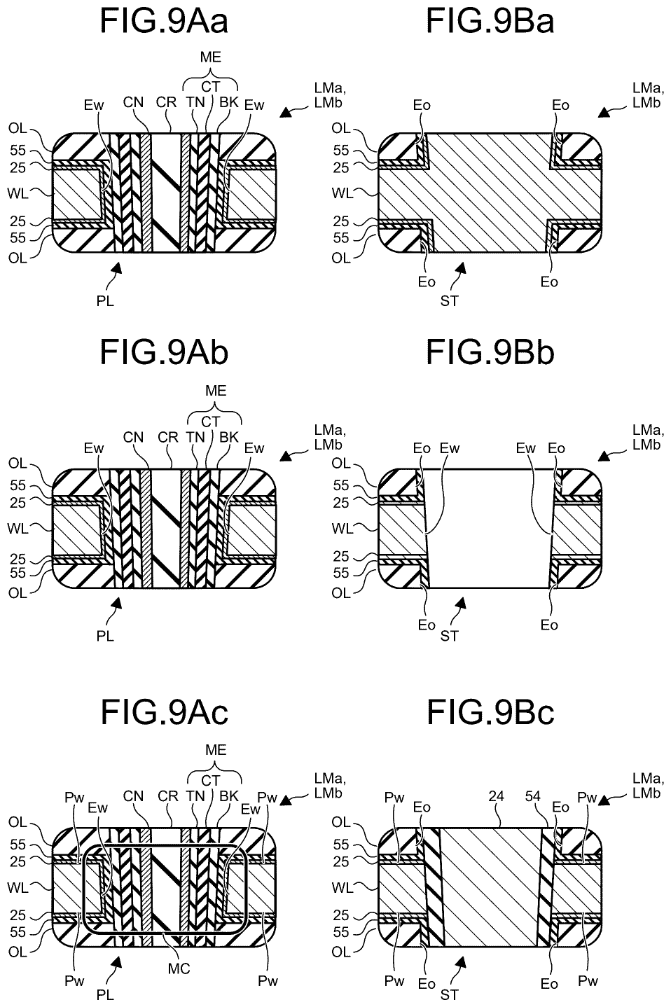

More specifically, FIGS. 8Aa to 8Ad and FIGS. 9Aa to 9Ac each illustrate a cross section of a memory hole MH at a height position of an insulating layer NL, a gap layer GP, or a word line WL. FIGS. 8Ba to 8Bd and FIGS. 9Ba to 9Bc each illustrate a cross section of a slit ST at a height position of an insulating layer NL, a gap layer GP, or a word line WL.

As illustrated in FIGS. 8Aa and 8Ba, it is assumed that each of the pillars PL and each of the slits ST has been formed in the stacked bodies LMsa and LMsb including each of the insulating layers NL before replacement. End surfaces En and Eo of the insulating layers NL and OL face side surfaces of the pillar PL and an inside of the slit ST, respectively.

As illustrated in FIGS. 8Ab and 8Bb, when the removing liquid for the insulating layer NL, such as thermal phosphoric acid, is caused to flow into the stacked bodies LMsa and LMsb through the slit ST, the insulating layer NL is removed, and the gap layers GP are formed between the plurality of insulating layers OL. Therefore, the stacked bodies LMga and LMgb are formed. In addition, the inside of the slit ST is in communication with the newly formed gap layers GP in side surfaces, and part of side surfaces Ep of the pillar PL face the gap layers GP.

Thereafter, as described below, a metal oxide layer 55, a metal nitride layer 25, and the word line WL are sequentially formed in each of the gap layers GP by, for example, an atomic layer deposition (ALD) method or the like.

As illustrated in FIGS. 8Ac and 8Bc, a source gas for the metal oxide layer 55 is supplied into the gap layer GP to form the metal oxide layer 55.

At this time, when the metal oxide layer 55 is an aluminum oxide layer or the like, a source gas such as an aluminum chloride (AlCl₃) gas serving as a source of aluminum and an oxygen-containing gas such as an oxygen gas are supplied into the gap layer GP. These source gases may be supplied in parallel so as to have at least a period for simultaneous supply of the source gases, or may be supplied all the time simultaneously by starting and stopping the supply at the same timing. Alternatively, these source gases may be alternately and repeatedly supplied one by one.

Each time of the alternate and repeated supply of the source gases, the source gas for aluminum is supplied for a period of forming an aluminum layer having a thickness of one to several atoms, and then the oxygen-containing gas is supplied for a period necessary to oxidize the aluminum layer having a thickness of one to several atoms. As described above, repeating a supply cycle of the source gas for aluminum and the oxygen-containing gas until the aluminum oxide layer having a desired layer thickness is obtained forms the metal oxide layer 55 on upper and lower surfaces Po of the insulating layers OL exposed above and below the gap layer GP.

Furthermore, in the vicinity of the pillar PL, the metal oxide layer 55 is formed on the upper and lower surfaces Po of the insulating layers OL, and is also formed on the side surfaces Ep of the pillar PL exposed further into the gap layer GP from the upper and lower surfaces of the insulating layers OL. Meanwhile, in the vicinity of the slit ST, the metal oxide layer 55 is further formed also on the end surfaces Eo of the insulating layers OL facing the inside of the slit ST, from the upper and lower surfaces Po of the insulating layers OL.

As illustrated in FIGS. 8Ad and 8Bd, a source gas for the metal nitride layer 25 is supplied into the gap layer GP in which the metal oxide layer 55 is formed to form the metal nitride layer 25.

At this time, in a case where the metal nitride layer 25 is the composite metal nitride layer containing molybdenum as the main component, a source gas such as a molybdenum dichloride dioxide (MoO₂Cl₂) gas serving as a source of molybdenum, a source gas serving as a source of the other metal such as titanium, aluminum, nickel, niobium, or cobalt, and a nitrogen-containing gas such as ammonia gas are supplied into the gap layer GP.

Furthermore, at this time, it is preferable to adjust a ratio of an amount of the source gas for the other metal supplied to an amount of the source gas for molybdenum supplied so that a ratio of the other metal to molybdenum in the metal nitride layer 25 is 0.5 atom % or more and 3 atom % or less. Here, a supply amount ratio of each of these source gases is calculated by using a supply amount per unit time of each of these source gases and a total of supply time.

When the other metal is titanium, aluminum, nickel, niobium, or cobalt, for example, a metal chloride gas such as a titanium chloride (TiCl₄) gas, an aluminum chloride (AlCl₃) gas, a nickel chloride (NiCl₂) gas, or a niobium chloride (NbCl₅) gas can be used as the source gas. Furthermore, in addition to the nitrogen-containing gas such as ammonia gas, a reducing gas such as hydrogen (H₂) gas may be supplied to accelerate nitriding reaction of each metal by using the nitrogen-containing gas.

When these source gases are supplied, two or more gases or all of the gases may be supplied in parallel so as to have at least a period for simultaneous supply of the source gases, or may be supplied all the time simultaneously by starting and stopping the supply at the same timing. Alternatively, these source gases may be alternately and repeatedly supplied one by one.

Each time of the alternate and repeated supply of the source gases, the source gas for molybdenum and the source gas for the other metal are allowed to be supplied for a period of forming a metal layer having a thickness of one to several atoms. Furthermore, the nitrogen-containing gas is supplied for a period necessary to nitride the metal layer having a thickness of one to several atoms. As described above, at this time, the reducing gas may be supplied together with the nitrogen-containing gas.

Furthermore, at this time, the order of supplying the source gas for molybdenum, the source gas for the other metal, and the nitrogen-containing gas is not particularly limited. For example, after the source gas for one metal and the source gas for the other metal are supplied, the nitrogen-containing gas may be supplied, or the source gas for one metal, the nitrogen-containing gas, the source gas for the other metal, and the nitrogen-containing gas may be supplied in this order.

Repeating the supply cycle as described above until the composite metal nitride layer having the desired layer thickness is obtained forms the metal nitride layer 25 on the upper and lower surfaces Po of the insulating layers OL exposed above and below the gap layer GP through the metal oxide layer 55.

Furthermore, as in the metal oxide layer 55, in the vicinity of the pillar PL, the metal nitride layer 25 is formed on the upper and lower surfaces Po of the insulating layers OL through the metal oxide layer 55, and is also formed on the side surfaces Ep of the pillar PL exposed further into the gap layer GP from the upper and lower surfaces Po of the insulating layers OL through the metal oxide layer 55. Meanwhile, as in the metal oxide layer 55, in the vicinity of the slit ST, the metal nitride layer 25 is further formed also on the end surfaces Eo of the insulating layers OL facing the inside of the slit ST from the upper and lower surfaces Po of the insulating layers OL, through the metal oxide layer 55.

As described above, forming the metal nitride layer 25 by adding the other metal in addition to molybdenum as the main component makes it possible to raise the melting point of the metal nitride layer 25 relative to that of, for example, the metal nitride layer containing molybdenum as the main component without the other metal, that is, a molybdenum nitride (MoxNy) layer.

As illustrated in FIGS. 9Aa and 9Ba, a source gas for a metal forming the word line WL is supplied into the gap layer GP in which the metal oxide layer 55 and the metal nitride layer 25 are formed, thereby forming the word line WL.

At this time, when the word line WL is a molybdenum layer containing molybdenum as the main component, the source gas such as a molybdenum dichloride dioxide (MoO₂Cl₂) gas serving as a source of molybdenum is supplied into the gap layer GP. Therefore, the molybdenum layer with a thickness of one to several atoms is formed step by step, on the metal nitride layer 25 that has formed, through the metal oxide layer 55, on the upper and lower surfaces Po of the insulating layers OL.

Furthermore, at this time, when the molybdenum layer is formed using the metal nitride layer 25 described above as a base layer, the metal nitride layer 25 serves as the precursor, and nucleation of the molybdenum layer is facilitated. Therefore, it is possible to increase a deposition rate of the molybdenum layer. In addition, using the precursor such as the metal nitride layer 25 makes it possible to improve the morphology for smooth molybdenum layer to suppress occurrence of voids and the like in the molybdenum layer.

Furthermore, the molybdenum layer is preferably formed at a high temperature equal to or higher than a predetermined temperature. Therefore, it is possible to further increase the deposition rate of the molybdenum layer. However, the formation at high temperature requires heat resistance of the metal nitride layer 25 serving as the base of the molybdenum layer. As described above, when the metal nitride layer 25 is formed, the other metal is added to molybdenum to raise the melting point of the metal nitride layer 25, and therefore, the metal nitride layer 25 can have sufficient heat resistance.

As described above, due to supplying the source gas for molybdenum continuously for a predetermined period, a gap remaining in the gap layer GP is filled with the molybdenum layer, and the plurality of the word lines WL are formed. Therefore, the stacked bodies LMa and LMb are formed, and each of the word lines WL has the end surface Ew facing the side surface of the pillar PL.

Note that during forming the word lines WL, the select gate lines SGD and SGS are also similarly formed. However, as described above, at this point of time, the select gate lines SGD are in a state before being separated by the separation layers SHE.

After the pluralities of the word lines WL and the select gate lines SGD and SGS are formed, the insides of the slits ST are being partially or entirely filled with the molybdenum layer.

As illustrated in FIGS. 9Ab and 9Bb, the molybdenum layer filled in each slit ST is removed. Therefore, each of the word lines WL has the end surface Ew facing the inside of the slit ST. Furthermore, the metal nitride layer 25 formed on the end surface Eo of each insulating layer OL facing the inside of the slit ST is exposed again.

In addition, the metal nitride layer 25 formed on the end surface Eo of each insulating layer OL and exposed in the slit ST is removed. This configuration prevents electrical conduction between the word lines WL in different layers formed thereafter, through the metal nitride layer 25 on the end surface Eo of the insulating layer OL. At this time, the metal oxide layer 55 on the end surface Eo of each insulating layer OL may or may not be removed together with the metal nitride layer 25. This is because the metal oxide layer 55 has substantially no conductivity, and there is no concern that electrical conduction between the word lines WL of different layers through the metal oxide layer 55.

As illustrated in FIGS. 9Ac and 9Bc, the insulating layer 54 is formed on the side walls of the slit ST, and the conductive layer 24 is formed in the remaining gap in the slit ST. Therefore, the plate-shaped portion LI is formed.

Note that the metal oxide layer 55, the metal nitride layer 25, the word line WL, and the like are formed by the ALD method or the like upon the replacement process for the word line WL and the like. However, the metal oxide layer 55, the metal nitride layer 25, the word line WL, and the like may be formed by another method such as a chemical vapor deposition (CVD) method.

### (Review)

In the semiconductor device, use of a molybdenum layer excellent in microfabrication capability for metal wiring or the like, high integration of the semiconductor device can be further achieved. When a molybdenum layer is used for metal wiring or the like, a liner layer such as a molybdenum nitride layer as a precursor is formed prior to use of the molybdenum layer, in some cases. This is because deposition with the simple substance of molybdenum without using the precursor hardly accelerates deposition of the molybdenum layer.

However, when a high-temperature condition is used in deposition of the molybdenum layer, the liner layer such as the molybdenum nitride layer melts, moves in the layer, and aggregates, and the flatness of the entire metal wiring deteriorates, in some cases. Meanwhile, when the molybdenum layer is deposited under a low temperature condition, the deposition rate of the molybdenum layer decreases with poor productivity.

The semiconductor device 1 according to the embodiment includes the word line WL containing molybdenum as the main component and the metal nitride layer 25. The metal nitride layer 25 contains molybdenum as the main component, and contains the other metal at least partially alloyed with molybdenum.

Therefore, even when the high temperature condition is used in forming the word line WL, the melting point of the metal nitride layer 25 is raised to suppress the aggregation of the metal nitride layer 25. Therefore, it is possible to improve the flatness of the word line WL and the metal nitride layer 25 while increasing the productivity.

According to the semiconductor device 1 of the embodiment, the other metal of the metal nitride layer 25 is at least one of titanium, aluminum, nickel, niobium, or cobalt. It is known that some or all of these metals are alloyed with molybdenum by being added to molybdenum, and the melting point of the alloyed molybdenum is raised. Therefore, the melting point of the metal nitride layer 25 can be raised.

### OTHER EMBODIMENTS

In the embodiment described above, the semiconductor device 1 includes the stacked body LM having a 2-tier structure in which two stacked bodies LMa and LMb are stacked vertically. However, the structure of the stacked body is not limited to the 2-tier structure, and may be a 1-tier structure or 3-tier structure or more.

Furthermore, in the embodiment described above, the pillar PL and the like are connected to the source line SL on the side surface of the channel layer CN, but the present invention is not limited thereto. For example, the pillar may be configured to be connected to the source line at a lower end of the channel layer by removing the memory layer on the bottom surface of the pillar.

In addition, in the embodiment described above, the peripheral circuit CBA is arranged above the stacked body LM. However, the peripheral circuits may be arranged in the same layer as the stacked body or below the stacked body LM. In the configuration arranging the peripheral circuit in the same layer as the stacked body, the stacked body can be formed at a position different from the positions of the peripheral circuits on the semiconductor substrate on which the peripheral circuits are formed. In the configuration arranging the peripheral circuit under the stacked body, the stacked body can be formed over the semiconductor substrate on which the peripheral circuits are formed.

In the embodiment described above, the semiconductor device 1 is the semiconductor storage device such as a three-dimensional nonvolatile memory. However, the interconnection layer including the first metal-containing layer and the second metal-containing layer which are described above are applicable to another semiconductor devices such as a dynamic random access memory (DRAM) or a logic semiconductor. For example, when the interconnection layer is applied to a semiconductor device other than the three-dimensional nonvolatile memory, the interconnection layer is formed by a method other than the replacement process, in some cases.

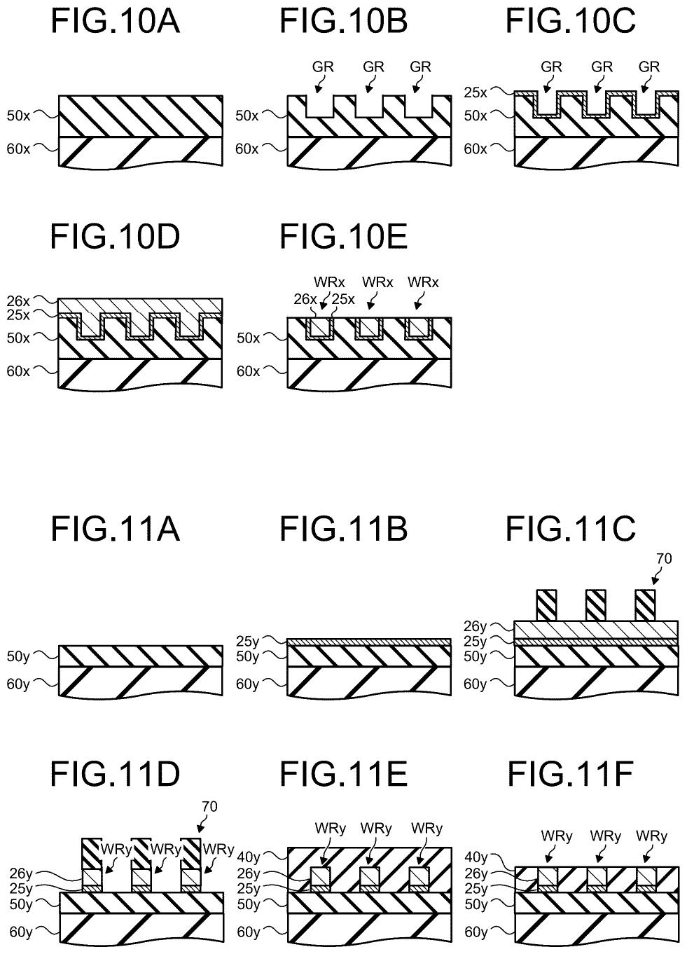

In the following, FIGS. 10A to 11 F illustrate examples of other forming methods for interconnection layers WRx and WRy. Metal-containing layers 26x and 26y in the following interconnection layers WRx and WEy are examples of the first metal-containing layer, and liner layers 25x and 25y are examples of the second metal-containing layer.

FIGS. 10A to 11F are cross-sectional views sequentially illustrating part of a procedure of a method of forming interconnection layers WRx and WRy according to other embodiments. In the examples of FIGS. 10A to 10E, the interconnection layer WRx is formed by a damascene method, and in the examples of FIGS. 11A to 11F, the interconnection layer WRy is formed using a lithography technique and an etching technique.

As illustrated in FIG. 10A, an insulating layer 50x such as a silicon oxide layer is formed on a base layer 60x made of any material. As illustrated in FIG. 10B, a plurality of grooves GR are formed in the insulating layer 50x.

As illustrated in FIG. 10C, as in the metal nitride layer 25 described above, the liner layer 25x, which is, for example, a nitride layer containing molybdenum as a main component and containing another metal, is formed on an upper surface of the insulating layer 50x and side surfaces and a bottom surface of each of the grooves GR. As illustrated in FIG. 10D, the metal-containing layer 26x containing molybdenum as a main component is filled in each groove GR in the insulating layer 50x in which the liner layer 25x is formed, as in the word line WL described above. At this time, the metal-containing layer 26x is also formed on the upper surface of the insulating layer 50x through the liner layer 25x. As in the embodiment described above, the compositions of the metal-containing layer 26x and the liner layer 25x are analyzed using, for example, EDS. In the EDS, a boundary between the metal-containing layer 26x and the liner layer 25x cannot be clearly distinguished, in some cases. However, the metal content is different between layers, and therefore, even when the boundary between the metal-containing layer 26x and the liner layer 25x cannot be clearly determined in EDS, the metal-containing layer 26x and the liner layer 25x each having a composition similar to that of the embodiment described above are included in the present configuration.

As illustrated in FIG. 10E, the metal-containing layer 26x and the liner layer 25x which are formed on the upper surface of the insulating layer 50x are sequentially removed by CMP or the like. Therefore, the interconnection layers WRx are formed that includes the metal-containing layer 26x and the liner layer 25x covering side surfaces and a bottom surface of the metal-containing layer 26x.

For example, a method of forming the interconnection layers WRx and the like with the grooves GRx formed in the insulating layer 50x as a mold in this manner is also referred to as the damascene method. Meanwhile, in a method of FIGS. 11A to 11F described below, an etching process is performed with a resist pattern 70 as a mask to obtain the interconnection layers WRy having a desired shape.

As illustrated in FIG. 11A, an insulating layer 50y such as a silicon oxide layer is formed on a base layer 60y made of any material.

As illustrated in FIG. 11B, as in the metal nitride layer 25 described above, the liner layer 25y, which is, for example, a nitride layer containing molybdenum as a main component and containing another metal, is formed on an upper surface of the insulating layer 50y. As illustrated in FIG. 11C, the metal-containing layer 26y containing molybdenum as a main component is formed on the liner layer 25y, as in the word line WL described above. Note that as in the embodiment described above, the compositions of the metal-containing layer 26y and the liner layer 25y are analyzed using, for example, EDS. In the EDS, a boundary between the metal-containing layer 26y and the liner layer 25y cannot be clearly distinguished, in some cases. However, the metal content is different between layers, and therefore, even when the boundary between the metal-containing layer 26y and the liner layer 25y cannot be clearly distinguished in EDS, the metal-containing layer 26y and the liner layer 25y each having a composition similar to that of the embodiment described above are included in the present configuration. In addition, the resist pattern 70 such as a photoresist layer is formed on an upper surface of the metal-containing layer 26y.

As illustrated in FIG. 11D, using the resist pattern 70 as the mask, the metal-containing layer 26y and the liner layer 25y are sequentially processed by etching or the like. Therefore, the interconnection layers WRy are formed that includes the metal-containing layer 26y and the liner layer 25y covering a bottom surface of the metal-containing layer 26y.

As illustrated in FIG. 11E, after the resist pattern 70 is removed, an insulating layer 40y such as a silicon oxide layer covering the interconnection layers WRy is formed. As illustrated in FIG. 11F, the insulating layer 40y is polished by CMP or the like to expose an upper surface of each of the interconnection layers WRy from an upper surface of the insulating layer 40y.

As described above, the interconnection layers WRx and WRy can be formed by various methods other than the replacement process described above. However, in the above, in the examples of FIGS. 10A to 11F, use of the damascene method of FIGS. 10A to 10E having an excellent microfabrication capability facilitates fine formation of the interconnection layer WRx.

Note that, also in the above examples of FIGS. 10A to 11F, the interconnection layers may be formed by an ALD method or the like, or may be formed by a CVD method or the like, as in the embodiments described above.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a semiconductor substrate;
an insulating layer that is provided above the semiconductor substrate; and
an interconnection layer that includes a first metal-containing layer containing a first metal as a main component, and a second metal-containing layer containing the first metal as the main component and being different from the first metal-containing layer, the second metal-containing layer being provided on the insulating layer, the first metal-containing layer being provided on the second metal-containing layer,
wherein the second metal-containing layer includes the first metal and a second metal different from the first metal, and has a proportion of the first metal smaller than a proportion of the first metal in the first metal-containing layer.

2. The semiconductor device according to claim 1, wherein
the first metal is Mo, and
the second metal-containing layer further includes N.

3. The semiconductor device according to claim 1, wherein
the first metal is Mo,
the second metal is at least one selected from the group consisting of Ti, Al, Ni, Nb, and Co, and
the second metal-containing layer has a melting point higher than that of a molybdenum nitride (MoxNy).

4. The semiconductor device according to claim 1, further comprising:
a stacked body in which a plurality of word lines is separately stacked; and
a pillar that includes a semiconductor layer extending in the stacked body in a stacking direction of the stacked body,
wherein each of the plurality of word lines is the interconnection layer.

5. The semiconductor device according to claim 4, wherein
the insulating layer is a metal oxide layer, and
the second metal-containing layer is covered with the metal oxide layer.

6. The semiconductor device according to claim 1, wherein
a ratio of the second metal to the first metal in the second metal-containing layer is 0.5 atom % or more and 3 atom % or less.

7. The semiconductor device according to claim 1, wherein
the first metal-containing layer is thicker than the second metal-containing layer.

8. A semiconductor device comprising:
a stacked body in which a plurality of interconnection layers and a plurality of insulating layers are alternately stacked one by one; and
a pillar that includes a semiconductor layer extending in the stacked body in a stacking direction of the stacked body,
wherein each of the plurality of interconnection layers includes:
a first metal-containing layer that contains a first metal as a main component; and
a second metal-containing layer that contains the first metal as the main component, the second metal-containing layer being different from the first metal-containing layer, the second metal-containing layer being provided on both surfaces of the first metal-containing layer in the stacking direction, and
the second metal-containing layer includes the first metal and a second metal different from the first metal, having a proportion of the first metal smaller than a proportion of the first metal in the first metal-containing layer.

9. The semiconductor device according to claim 8, wherein
the second metal-containing layer is provided on both surfaces of the first metal-containing layer in the stacking direction, and is provided on an end surface of the first metal-containing layer facing a side surface of the pillar.

10. The semiconductor device according to claim 8, further comprising:
a plate-shaped portion that extends in the stacked body in the stacking direction and a first direction intersecting the stacking direction, and divides the stacked body in a second direction, the second direction intersecting the stacking direction and the first direction; and
a metal oxide layer that is provided on each of both surfaces of the plurality of interconnection layers in the stacking direction,
wherein the metal oxide layer is provided on each of both surfaces of the plurality of interconnection layers in the stacking direction, and is provided on an end surface of each of the plurality of insulating layers facing a side surface of the plate-shaped portion.

11. The semiconductor device according to claim 8, wherein
the first metal is Mo,
the second metal is at least one selected from the group consisting of Ti, Al, Ni, Nb, and Co, and
the second metal-containing layer has a melting point higher than that of a molybdenum nitride (MoxNy).

12. The semiconductor device according to claim 8, wherein
a ratio of the second metal to the first metal in the second metal-containing layer is 0.5 atom % or more and 3 atom % or less.

13. A method of manufacturing a semiconductor device, the method comprising forming an interconnection layer including a first metal-containing layer containing a first metal as a main component and a second metal-containing layer containing the first metal as the main component and different from the first metal-containing layer, the method comprising:
forming a first insulating layer above a semiconductor substrate;
supplying a first gas serving as a source of the first metal, a second gas serving as a source of a second metal different from the first metal, and a nitrogen-containing gas onto the first insulating layer to form the second metal-containing layer; and
after stopping supply of the second gas and the nitrogen-containing gas, supplying the first gas onto the second metal-containing layer to form the first metal-containing layer.

14. The method of manufacturing a semiconductor device according to claim 13, wherein
the second metal-containing layer is formed using an atomic layer deposition method or a chemical vapor deposition method, and
at least two or more of the first gas, the second gas, and the nitrogen-containing gas are supplied in parallel.

15. The method of manufacturing a semiconductor device according to claim 14, wherein
the first gas is a source gas for Mo, and
the second gas is a source gas for at least one selected from the group consisting of Ti, Al, Ni, Nb, and Co.

16. The method of manufacturing a semiconductor device according to claim 14, further comprising
forming a first stacked body in which a plurality of second insulating layers is separately stacked,
wherein the interconnection layer is formed in each of gaps between the plurality of second insulating layers.

17. The method of manufacturing a semiconductor device according to claim 16, wherein
the first insulating layer is formed on each of both surfaces of the plurality of second insulating layers in a stacking direction, both surfaces being exposed in each of gaps between the plurality of second insulating layers,
the second metal-containing layer is formed, through the first insulating layer, on each of the both surfaces of the plurality of second insulating layers in the stacking direction by supplying the first gas, the second gas, and the nitrogen-containing gas to each of the gaps, the both surfaces being exposed in each of the gaps, and
the first metal-containing layer is formed by supplying the first gas after stopping supply of the second gas and the nitrogen-containing gas onto the second metal-containing layers formed on the both surfaces of the plurality of second insulating layers.

18. The method of manufacturing a semiconductor device according to claim 17, wherein
formation of the first stacked body includes:
forming a second stacked body in which the plurality of second insulating layers and a plurality of sacrificial layers are alternately stacked one by one; and
removing the plurality of sacrificial layers from the second stacked body.

19. The method of manufacturing a semiconductor device according to claim 18, wherein
formation of the first stacked body further includes forming a pillar having a semiconductor layer penetrating the second stacked body in a stacking direction of the plurality of sacrificial layers.

20. The method of manufacturing a semiconductor device according to claim 13, wherein
the second metal-containing layer is a metal nitride layer containing the first metal as the main component and having a ratio of the first metal smaller than a ratio of the first metal in the first metal-containing layer.
